(19) United States
(12) Patent Application Publication
(10) Pub. No.: US 2025/0096825 A1
(43) Pub. Date: Mar. 20, 2025

(54) DATA SIGNAL TRANSMITTERS AND INTEGRATED CIRCUIT DEVICES INCLUDING THE SAME

(71) Applicant: Samsung Electronics Co., Ltd., Suwon-si (KR)

(72) Inventors: Daechul Jeong, Suwon-si (KR); Seonkyoo Lee, Suwon-si (KR); Taesung Lee, Suwon-si (KR); Tongsung Kim, Suwon-si (KR)

(21) Appl. No.: 18/772,352

(22) Filed: Jul. 15, 2024

(30) Foreign Application Priority Data
Sep. 20, 2023 (KR) 10-2023-0125790

(51) Int. Cl. H04B 1/04; H03K 19/0185

(52) U.S. Cl. CPC H04B 1/04; H03K 19/018521

(57) ABSTRACT

A data signal transmitter includes a standby voltage generator, which is configured to selectively output: (i) a data signal during an active operation mode, and (ii) first and second different standby voltages during a standby operation mode, and a repeater block. The repeater block includes: a first CMOS inverter configured to receive the first standby voltage during the standby operation mode, and a second CMOS inverter configured to receive the second standby voltage during the standby operation mode.

### REFERENCE TO PRIORITY APPLICATION

This application claims priority from Korean Patent Application No. 10-2023-0125790, filed Sep. 20, 2023, the disclosure of which is hereby incorporated herein by reference.

### BACKGROUND

The present disclosure relates to data signal transmitters and integrated circuit devices including the same.

Due to a trend toward higher functionality of electronic devices, research on improving data transmission speeds between chip components, and research on low-power devices for reasons such as increasing a portability of electronic devices and preventing a performance degradation has increased substantially.

In relation to data transmission, high-speed data transmission devices have been proposed, and improvements are being made in propagation delay time within these devices. However, since it is often difficult to simultaneously improve the propagation delay time and prevent leakage currents due to device characteristics, techniques for adding power-gating circuits to the high-speed data transmission components continue to be proposed.

### SUMMARY

An embodiment provides a data signal transmitter with increased area efficiency and improved operation performance, while improving performance in data transmission speed and power consumption.

According to disclosed embodiments, a data signal transmitter is provided that includes a standby voltage generator configured to selectively output: (i) a data signal during an active operation mode, and (ii) first and second standby voltages, having different magnitudes from each other, during a standby operation mode; and a repeater block which includes: a first CMOS inverter configured to receive the first standby voltage during the standby operation mode, said first CMOS inverter including a first PMOS transistor and a first NMOS transistor having different threshold voltage magnitudes, and a second CMOS inverter configured to receive the second standby voltage during the standby operation mode, said second CMOS inverter including a second PMOS transistor having a threshold voltage magnitude that is smaller than the magnitude of the threshold voltage of the first PMOS transistor, and a second NMOS transistor having a threshold voltage magnitude that is greater than the magnitude of the threshold voltage of the first NMOS transistor.

According to another embodiment, a data signal transmitter is provided that includes a first mode setting transistor connected between a first node to which a power source voltage is provided in a standby operation mode and a second node that is different from the first node and to which a ground voltage is provided in the standby operation mode. The data signal transmitter also includes a first high-threshold voltage transistor including a gate terminal connected to the first node and a source terminal to which a power source voltage is applied, a first low-threshold voltage transistor including a gate terminal connected to the first node and a source terminal that is grounded and forming a threshold voltage smaller than the magnitude of the threshold voltage of the first high-threshold voltage transistor, a second low-threshold voltage transistor including a gate terminal connected to the second node and a source terminal to which a power source voltage is applied, and a second high-threshold voltage transistor including a gate terminal connected to the second node and a source terminal that is grounded, and forming a threshold voltage greater than the magnitude of the threshold voltage of the second low-threshold voltage transistor.

According to a further disclosed embodiment, an integrated circuit device is provided that a driver circuit configured to transmit data signals through a transmission line, a receiver circuit configured to receive the data signals through the transmission line and a data signal transmitter extending between portions of the transmission line. The data signal transmitter includes a standby voltage generator configured to provide first and second standby voltages, having different magnitude from each other, depending on whether the data signal of the driver circuit is output or not, a first CMOS inverter that is provided with the first standby voltage and includes a first PMOS transistor and a first NMOS transistor with different threshold voltage magnitudes, and a second CMOS inverter that is provided with the second standby voltage and includes a second PMOS transistor with a threshold voltage less than the magnitude of the threshold voltage of the first PMOS transistor and a second NMOS transistor with a threshold voltage greater than the magnitude of the threshold voltage of the first NMOS transistor.

### BRIEF DESCRIPTION OF THE DRAWINGS

FIG. 1 is a block diagram showing a part of a semiconductor device according to an embodiment.

FIG. 2 is a block diagram showing a data signal transmitter according to an embodiment.

FIG. 3 and FIG. 4 are circuit diagrams to explain a data signal transmitter according to an embodiment.

FIG. 5 and FIG. 6 are views to explain an operation of a data signal transmitter according to an embodiment.

FIG. 7 and FIG. 8 are views to explain an operation of a data signal transmitter according to an embodiment.

FIG. 9 is a view to explain a semiconductor device according to an embodiment.

FIG. 10 is a view to explain a semiconductor device according to an embodiment.

FIG. 11 is a view to explain a semiconductor device according to an embodiment.

### DETAILED DESCRIPTION OF EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure. In order to clarify the present disclosure, parts that are not connected with the description will be omitted, and the same elements or equivalents are referred to by the same reference numerals throughout the specification. Furthermore, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed. In addition, unless explicitly described to the contrary, the word “comprise”, and variations such as “comprises” or “comprising”, will be understood to imply the inclusion of stated elements but not the exclusion of any other elements.

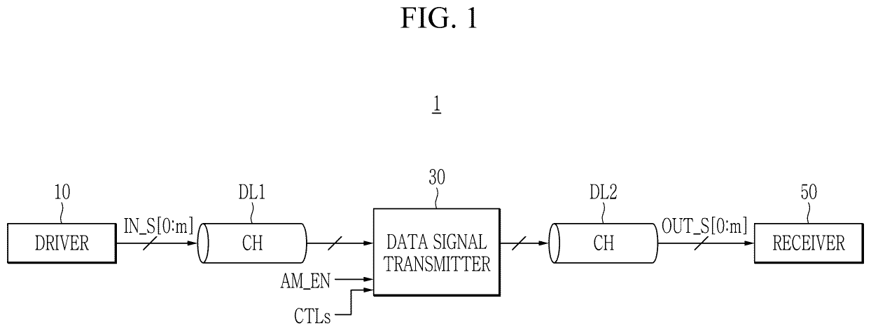

FIG. 1 is a block diagram showing a part of a semiconductor device according to an embodiment. FIG. 1 may be a view showing a circuit that performs a data transmission within a semiconductor device 1. Referring to FIG. 1, according to an embodiment, the semiconductor device 1 may be a semiconductor integrated circuit, particularly a low-power semiconductor integrated circuit. The semiconductor device 1 according to the embodiment can process and manage instructions and perform data processing operations. The semiconductor device 1 may be processors such as a CPU (central processing unit), GPU (Graphics Processing), NPU (Neural Processing Unit), DPU (Data Processing Unit), or a combination thereof, and may be a system on chip (SoC).

The semiconductor device 1 according to the embodiment is a main memory or a system memory of an electronic device and may be used as a temporary storage location for a data or as an execution space for various software codes. The semiconductor device 1 may include a dynamic random access memory (DRAM) device. However, the technical idea of the present disclosure is not limited thereto, it may be any one of volatile memory devices such as synchronous DRAM (SDRAM), double data rate SDRAM (DDR SDRAM), low power double data rate SDRAM (LPDDR SDRAM), and graphics double data rate SDRAM (GDDR SDRAM), DDR2 SDRAM, DDR3 SDRAM, DDR4 SDRAM, DDR5 SDRAM, etc. The semiconductor device 1 according to the embodiment may also be a storage device including a non-volatile memory that stores a data in a semi-permanent or substantially permanent form. The semiconductor device 1 may include a non-volatile memory such as NOR or NAND flash.

The semiconductor device 1 may include a driver circuit 10, a data signal transmitter 30, and a receiver circuit 50. The driver circuit 10 may drive a plurality of data input signals IN_S[0:m], which is a data signal to be output to a plurality of first transmission lines DL1. The driver circuit 10 according to the embodiment may receive the data processed by the semiconductor device 1 or stored temporarily or permanently and transmit the plurality of data input signals IN_S[0:m] through the plurality of first transmission line DL1. According to an embodiment, the driver circuit 10 may be included in a buffer, a data input/output circuit, or an interface circuit.

During a transmission process, the driver circuit 10 may control the current flowing through the constituent elements in the semiconductor device 1 and the voltage applied, or control other elements such as other components or devices. According to an embodiment, the driver circuit 10 may include an amplifier, a level shifter, a diode, etc.

The data signal transmitter 30 may prevent a channel loss in the plurality of transmission lines DL1 and DL2 by restoring the plurality of data input signals IN_S[0:m] input from the plurality of first transmission line DL1. The data signal transmitter 30 may be placed between the plurality of transmission lines DL1 and DL2, and the plurality of data output signals OUT_S[0:m], which is the data signal restored by the data signal transmitter 30, may be provided to the receiver circuit 50 through the plurality of second transmission lines DL2.

The data signal transmitter 30 according to the embodiment may receive a control signal including a standby control signal CTLs and an active mode enable signal AM_EN depending on whether the plurality of data input signals IN_S[0:m] of the driver circuit 10 is output. The operation mode of the data signal transmitter 30 may be changed based on the standby control signal CTLs and the active mode enable signal AM_EN.

According to an embodiment, as the driver circuit 10 outputs the plurality of data input signals IN_S[0:m], the active mode enable signal AM_EN, which is set as a turn on level, and the standby control signal CTLs, which correspond to the active mode enable signal AM_EN, may be input to the data signal transmitter 30. When the active mode enable signal AM_EN and the standby control signal CTLs are input as described above, the operation mode of the data signal transmitter 30 may be the active operation mode.

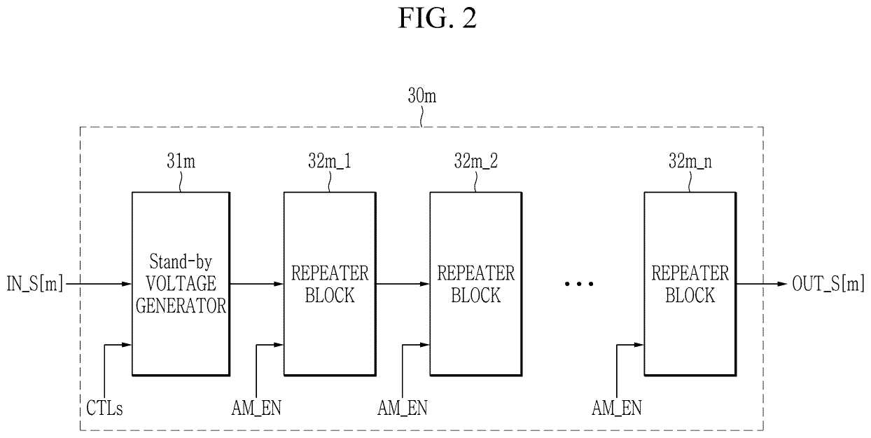

Also, as an example, as the driver circuit 10 does not output the plurality of data input signals IN_S[0:m], the active mode enable signal AM_EN, which is set as a turn off level, and the standby control signal CTLs corresponding to the active mode enable signal AM_EN may be input to the data signal transmitter 30. When the standby control signal CTLs is input as above, the operation mode of the data signal transmitter 30 may be a standby operation mode. In the standby operation mode, the data signal transmitter 30 is in a static state, and in the static state, repetitive charging/discharge operations by a data switching may be not performed at the output terminal of a repeater blocks (not shown) within the data signal transmitter 30. The detailed description of the configuration within the data signal transmitter 30 is explained later with reference to FIG. 2 to FIG. 4.

In FIG. 1, only the plurality of data signals are shown moving from the driver circuit 10 to the plurality of first transmission line DL1, the data signal transmitter 30, the plurality of second transmission line DL2, and the receiver circuit 50 in that order. However, it is not limited thereto, and according to the operation of semiconductor device 1, the driver circuit 10 may operate as a receiver circuit to receive the data signals, and receiver circuit 50 may operate as a driver circuit to output the data signals. According to an embodiment, the plurality of first transmission line DL1 and the plurality of second transmission line DL2 may be data channels that transmit data in both directions, and the data signal transmitter 30 may transmit data signals in either direction according to the operation of semiconductor device 1.

In the drawing, the data signal transmitter 30 is shown as being placed between the plurality of transmission lines DL1 and DL2, but according to an embodiment, the data signal transmitter 30 may be placed in a configuration where a data is transmitted and received, such as the driver circuit 10, the receiver circuit 50, etc. And, based on the arrangement of the data signal transmitter 30 as described above, the performance of data signal transmission and power consumption of the driver circuit 10 and the receiver circuit 50 may be advantageously improved.

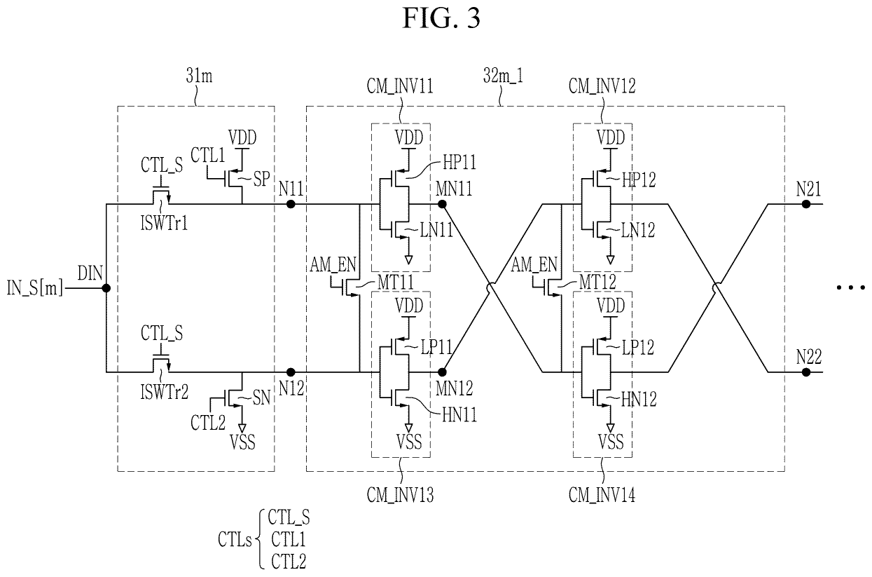

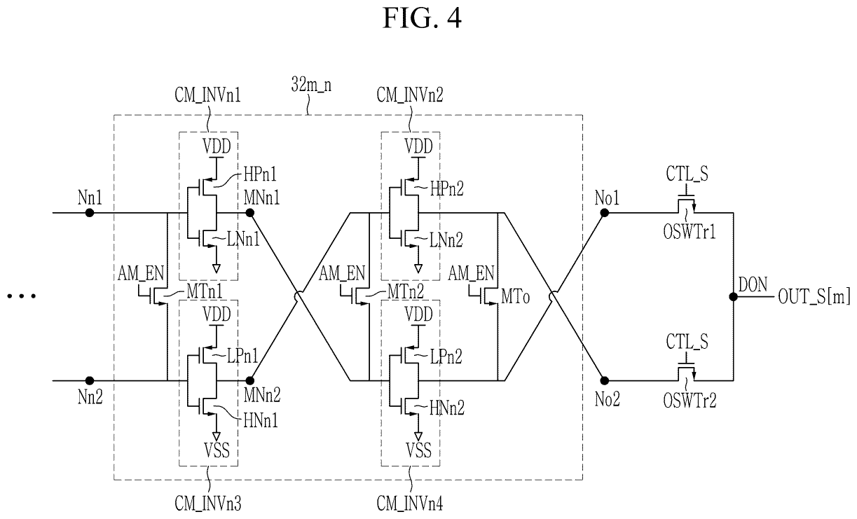

FIG. 2 is a block diagram showing a data signal transmitter according to an embodiment; whereas FIG. 3 and FIG. 4 are circuit diagrams to explain a data signal transmitter according to an embodiment. Referring to FIG. 1 and FIG. 2, the data signal transmitter 30 may include an m-th data signal transmitter 30m corresponding to an m-th data input signal IN_S[m] and an m-th data output signal OUT_S[m]. The m-th data signal transmitter 30m may restore the m-th data input signal IN_S[m] and output the m-th data output signal OUT_S[m]. the m is an integer of 0 or more. Although not shown in the drawing, according to the embodiment, the data signal transmitter 30 may include a plurality of data signal transmitters corresponding to each of the remaining plurality of data input signals IN_S[0:m] and plurality of data output signals OUT_S[0:m]. The plurality of data signal transmitter may correspond to the m-th data signal transmitter 30m, and the description of the plurality of data signal transmitter may be replaced with the description of the m-th data signal transmitter 30m.

Additionally referring to FIG. 3 and FIG. 4, the m-th data signal transmitter 30m may include an m-th standby voltage generator 31m, (m_1)-th to (m_n)-th repeater blocks 32m_1 to 32m_n, a first output switch transistor OSWTr1, and a second output switch transistor OSWTr2. According to an embodiment, n may be an integer greater than or equal to 2. Depending on the operation mode of the m-th data signal transmitter 30m, the m-th standby voltage generator 31m may be provided with the standby control signal CTLs, and may output the m-th data input signal IN_S[m] that is branched from the data input node DIN and input to the (m_1)-th repeater block 32m_1 through the first_first node N11 and the first_second node N12.

Depending on the operation mode of the m-th data signal transmitter 30m, the m-th standby voltage generator 31m may provide the standby voltage to the (m_1)-th repeater block 32m_1 through the first_first node N11 and the first_second node N12. The m-th standby voltage generator 31m may include a first input switch transistor ISWTr1, a second input switch transistor ISWTr2, a standby voltage PMOS transistor SP, and a standby voltage NMOS transistor NP.

The first input switch transistor ISWTr1 may be connected between the data input node DIN and the first_first node N11. When the first input switch transistor ISWTr1 is turned on by the switch control signal CTL_S that is one of the standby control signal CTLs, a short-circuit may be formed between the data input node DIN and the first_first node N11. When the first input switch transistor ISWTr1 is turned off by the switch control signal CTL_S, the connection between the data input node DIN and the first_first node N11 may be opened.

The second input switch transistor ISWTr2 may be connected between the data input node DIN and the first_second node N12; when the second input switch transistor ISWTr2 is turned on by the switch control signal CTL_S, a short circuit may be formed between the data input node DIN and the first_second node N12. When the second input switch transistor ISWTr2 is turned off by the switch control signal CTL_S, the connection between the data input node DIN and the first_second node N12 may be opened.

The first and second input switch transistors ISWTr1 and ISWTR2 may provide the m-th data input signal IN_S[m], which is branched from the data input node DIN and input to the first_first node N11 and the first_second node N12 based on the switch control signal CTL_S, or may block the input m-th data input signal IN_S[m]. According to an embodiment, the first and second input switch transistors ISWTr1 and ISWTR2 may be NMOS transistors, but are not limited thereto.

For the standby voltage PMOS transistor SP, a power source voltage VDD may be applied to the source terminal, and the drain terminal may be connected to the first_first node N11. When the standby voltage PMOS transistor SP is turned on by the first standby control signal CTL1, which is one of the standby control signal CTLs, the power source voltage VDD may operate as a standby voltage and may be provided to the first_first node N11. Depending on the operation mode of the m-th data signal transmitter 30m, the standby voltage PMOS transistor SP may be turned off by the first standby control signal CTL1 to block the power source voltage VDD.

For the standby voltage NMOS transistor SN, a ground voltage VSS may be applied to the source terminal, and the drain terminal may be connected to the first_second node N12. When the standby voltage NMOS transistor SN is turned on by the second standby control signal CTL2, which is another one of the standby control signal CTLs, the ground voltage VSS may operate as a standby voltage and may be provided to the first_second node N12. Depending on the operation mode of the m-th data signal transmitter 30m, the standby voltage PMOS transistor SP may be turned off by the first standby control signal CTL1 to block the ground voltage VSS.

The (m_1)-th to (m_n)-th repeater blocks 32m_1 to 32m_n may be connected in series between the data input node DIN and the data output node DON. The (m_1)-th to (m_n)-th repeater blocks 32m_1 to 32m_n may include a CMOS inverter chain connected in series. The m_1 to (m_n)-th repeater blocks 32m_1 to 32m_n may operate as a chain for a plurality of CMOS inverters connected in parallel depending on the operation mode of the m-th data signal transmitter 30m.

Depending on the operation mode of the m-th data signal transmitter 30m, the m-th standby voltage generator 31m may receive the active mode enable signal AM_EN. The (m_1)-th to (m_n)-th repeater blocks 32m_1 to 32m_n may perform a restoration operation for the m-th data input signal IN_S[m] when the active mode enable signal AM_EN is input. The m-th data input signal IN_S[m] input through the data input node DIN may be restored into the m-th data output signal OUT_S[m] and output to the data output node DON.

If the active mode enable signal AM_EN is not input, the (m_1)-th to (m_n)-th repeater blocks 32m_1 to 32m_n may be maintained in a static state in which a data switching does not occur by the standby voltage provided to the m-th standby voltage generator 31m. The (m_1)-th to (m_n)-th repeater blocks 32m_1 to 32m_n may include identical or corresponding configurations. In the following, the (m_1)-th repeater block 32m_1 is described, and the remaining repeater blocks other than the (m_1)-th repeater block 32m_1 are explained focusing on the differences from the (m_1)-th repeater block 32m_1.

The (m_1)-th repeater block 32m_1 may be placed between the first_first node N11 and the second_first node N21, and between the first_second node N12 and the second_second node N22. The (m_1)-th repeater block 32m_1 may be connected to the m-th standby voltage generator 31m, which is located at the front end, through the first_first node N11 and the first_second node N12, which are input terminals. The (m_1)-th repeater block 32m_1 may be connected to the m-th_2 repeater block 32m_2, which is located at the rear end, through the second_first node N21 and the second_second node N22, which are output terminals.

The (m_1)-th repeater block 32m_1 may include first_first to first_fourth CMOS inverters CM_INV11 to CM_INV14, and first_first to first_second mode setting transistors MT11 to MT12. The first_first CMOS inverter CM_INV11 and the first_fourth CMOS inverter CM_INV14 can be connected in series between the first_first node N11 and the second_first node N21, and the first_third CMOS inverter CM_INV13 and the second CMOS inverter CM_INV12 may be connected in series between the first_second node N12 and the second_second node N22.

The input terminal of the first_first CMOS inverter CM_INV11 may be connected to the m-th standby voltage generator 31m through the first_first node N11, and the output terminal of the first_first CMOS inverter CM_INV11 may be connected to the input terminal of the first_fourth CMOS inverter CM_INV14 through a first_first middle node MN11.

The first_first CMOS inverter CM_INV11 may include a first_first high-threshold voltage PMOS transistor HP11 and a first_first low-threshold voltage NMOS transistor LN11. For the first_first high-threshold voltage PMOS transistor HP11, the gate terminal may be connected to the first_first node N11, a power source voltage VDD may be applied to the source terminal, and the drain terminal may be connected to the first_first middle node MN11. The first_first low-threshold voltage NMOS transistor LN11 may include the gate terminal connected to the first_first node N11, the source terminal grounded to a ground voltage VSS, and the drain terminal connected to the first_first middle node MN11. The threshold voltage of the first_first high-threshold voltage PMOS transistor HP11 may be larger than the magnitude of the threshold voltage of the first_first low-threshold voltage NMOS transistor LN11. In the present disclosure, the magnitude of the threshold voltage of the PMOS transistor and the NMOS transistor may be formed by factors such as the base material of the gate and the substrate, the thickness of the gate oxide layer, and the impurity concentration doped on the substrate, and each factor may change depending on the embodiment.

The input terminal of the first_second CMOS inverter CM_INV12 may be connected to the output terminal of the first_third CMOS inverter CM_INV13 through the first_second middle node MN12, and the output terminal of the first_second CMOS inverter CM_INV12 may be connected to the input terminal of the m-th_2 repeater block 32m_2 through the second_second node N22.

The first_second CMOS inverter CM_INV12 may include a first_second high-threshold voltage PMOS transistor HP12 and a first_second low-threshold voltage NMOS transistor LN12. The first_second high-threshold voltage PMOS transistor HP12 may include the gate terminal connected to the first_second middle node MN12, the source terminal to which the power source voltage VDD is applied, and the drain terminal connected to the second_second node N22. The first_second low-threshold voltage NMOS transistor LN12 may include the gate terminal connected to the first_second middle node MN12, the source terminal grounded to the ground voltage VSS, and the drain terminal connected to the second_second node N22. The threshold voltage of the first_second high-threshold voltage PMOS transistor HP12 may be larger than the magnitude of the threshold voltage of the first_second low-threshold voltage NMOS transistor LN12.

The input terminal of the first_third CMOS inverter CM_INV13 may be connected to the m-th standby voltage generator 31m through the first_second node N12, and the output terminal of the first_third CMOS inverter CM_INV13 may be connected to the input terminal of the first_third CMOS inverter CM_INV13 through the first_second middle node MN12.

The first_third CMOS inverter CM_INV13 may include a first_first low-threshold voltage PMOS transistor LP11 and a first_first high-threshold voltage NMOS transistor LP11. The first_first low-threshold voltage PMOS transistor LP11 may include the gate terminal connected to the first_second node N12, the source terminal to which the power source voltage VDD is applied, and the drain terminal connected to the first_second middle node MN12. The first_first high-threshold voltage NMOS transistor HN11 may include the gate terminal connected to the first_second node N12, the source terminal grounded to the ground voltage VSS, and the drain terminal connected to the first_second middle node MN12. The magnitude of the threshold voltage of the first_first high-threshold voltage NMOS transistor HN11 may be larger than the magnitude of the threshold voltage of the first_first low-threshold voltage PMOS transistor LP11.

According to an embodiment, the magnitude of the threshold voltage of the first_first high-threshold voltage NMOS transistor HN11 may be equal to the magnitude of the threshold voltage of the first_first high-threshold voltage PMOS transistor HP11, however it is not limited thereto. According to an embodiment, the magnitude of the threshold voltage of the first_first low-threshold voltage PMOS transistor LP11 and the magnitude of the threshold voltage of the first_first low-threshold voltage NMOS transistor LN11 may be the same, but are not limited thereto.

The input terminal of the first_fourth CMOS inverter CM_INV14 may be connected to the output terminal of the first_first CMOS inverter CM_INV11 through the first_first middle node MN11, and the output terminal of the first_fourth CMOS inverter CM_INV14 may be connected to the input terminal of the m-th_2 repeater block 32m_2 through the second_first node N21. The first_fourth CMOS inverter CM_INV14 may include a first_second low-threshold voltage PMOS transistor LP12 and a first_second high-threshold voltage NMOS transistor HN12. The first_second low-threshold voltage PMOS transistor LP12 may include the gate terminal connected to the first_first middle node MN11, the source terminal to which the power source voltage VDD is applied, and the drain terminal connected to the second_first node N21. The first_second high-threshold voltage NMOS transistor HN12 may include the gate terminal connected to the first_first middle node MN11, the source terminal grounded to the ground voltage VSS, and the drain terminal connected to the second_first node N21. The magnitude of the threshold voltage of the first_second high-threshold voltage NMOS transistor HN12 may be greater than the threshold voltage of the first_second low-threshold voltage PMOS transistor LP12.

According to an embodiment, the magnitude of the threshold voltage of the first_second high-threshold voltage NMOS transistor HN12 may be the same as the magnitude of the threshold voltage of the first_second high-threshold voltage PMOS transistor HP12, but is not limited thereto. According to an embodiment, the magnitude of the threshold voltage of the first_second low-threshold voltage PMOS transistor LP12 and the magnitude of the threshold voltage of the first_second low-threshold voltage NMOS transistor LN12 may be the same, but are not limited thereto.

In the (m_1)-th repeater block 32m_1, the magnitudes of the threshold voltages of the first_first high-threshold voltage PMOS transistor HP11, the first_first high-threshold voltage NMOS transistor HN11, the first_second high-threshold voltage PMOS transistor HP12, and the first_second high-threshold voltage NMOS transistor HN12 may be larger than the magnitudes of the threshold voltages of the first_first low-threshold voltage PMOS transistor LP11, the first_first low-threshold voltage NMOS transistor LN11, the first_second low-threshold voltage PMOS transistor LP12, and the first_second low-threshold voltage NMOS transistor LN12.

Conversely, the magnitudes of the threshold voltages of the first_first low-threshold voltage PMOS transistor LP11, the first_first low-threshold voltage NMOS transistor LN11, the first_second low-threshold voltage PMOS transistor LP12, and the first_second low-threshold voltage NMOS transistor LN12 may be smaller than the magnitudes of the threshold voltages of the first_first high-threshold voltage PMOS transistor HP11, the first_first high-threshold voltage NMOS transistor HN11, the first_second high-threshold voltage PMOS transistor HP12, and the first_second high-threshold voltage NMOS transistor HN12.

The first_first mode setting transistor MT11 may be connected to the first_first node N11 connected to the input terminal of the first_first CMOS inverter CM_INV11 and the first_second node N12 connected to the input terminal of the first_third CMOS inverter CM_INV13.

The first_second mode setting transistor MT12 may be connected between the first_first middle node MN11 connected to the output terminal of the first_first CMOS inverter CM_INV11 and the first_second middle node MN12 connected to the output terminal of the first_third CMOS inverter CM_INV13. Accordingly, the first_second mode setting transistor MT12 may be connected to between the drain terminals of the first_first high-threshold voltage PMOS transistor HP11 and the first_first low-threshold voltage NMOS transistor LN11, and the drain terminals of the first_first low-threshold voltage PMOS transistor LP11 and the first_first high-threshold voltage NMOS transistor HN11. As shown, according to the operation mode of the m-th data signal transmitter 30m, the first_first and first_second mode setting transistors MT11 and MT12 may receive the active mode enable signal AM_EN.

When the first_first and first_second mode setting transistors MT11 and MT12 are provided with the active mode enable signal AM_EN, a conduction channel may be formed between the first_first node N11 and the first_second node N12 and between the first_first middle node MN11 and the first_second middle node MN12. Therefore, when the first_first and first_second mode setting transistors MT11 and MT12 are provided with the active mode enable signal AM_EN, the first_first CMOS inverter CM_INV11 and the first_third CMOS inverter CM_INV13 may be connected in parallel between the first_first node N11 and the first_first middle node MN11.

Although not shown, when the first_second mode setting transistor MT12 and the mode setting transistor placed between the second_first node N21 and the second_second node N22 receive the active mode enable signal AM_EN, the first_second CMOS inverter CM_INV12 and the first_fourth CMOS inverter CM_INV14 may be connected in parallel between the first_first middle node MN11 and the second_first node N21. If the first_first and first_second mode setting transistors MT11 and MT12 are not provided with the active mode enable signal AM_EN, the first_first node N11 and the first_second node N12, and the first_first middle node MN11 and the first_second middle node MN12 may not be electrically connected to each other. The first_first and first_second mode setting transistors MT11 and MT12 may be NMOS transistors in some embodiments, but are not limited thereto.

Among the (m_1)-th to (m_n)-th repeater blocks 32m_1 to 32m_n, the (m_n)-th repeater blocks 32m_1 to 32m_n may further include an output mode setting transistor MTo disposed between the first output node No1 and the second output node No2, which are connected to the output terminal. According to the operation mode of the m-th data signal transmitter 30m, the output mode setting transistor MTo may receive the active mode enable signal AM_EN. When the output mode setting transistor MTo receives the active mode enable signal AM_EN, a conduction channel may be formed between the first output node No1 and the second output node No2.

The first output switch transistor OSWTr1 and the second output switch transistor OSWTr2 may be connected to the output terminal of (m_n)-th repeater blocks 32m_1 to 32m_n. The first output switch transistor OSWTr1 may be connected to the output terminal of the n-th_4 CMOS inverter CM_INVn4 of the (m_n)-th repeater block 32m_n through the first output node No1, and the second output switch transistor OSWTr2 may be connected to the output terminal of the n-th_2 CMOS inverter CM_INVn2 of the (m_n)-th repeater block 32m_n through the second output node No2.

The first output switch transistor OSWTr1 may be connected between the first output node No1 and the data output node DON. When the first output switch transistor OSWTr1 is turned on by the switch control signal CTL_S, it may be short-circuited between the first output node No1 and the data output node DON. When the first output switch transistor OSWTr1 is turned off by the switch control signal CTL_S, the connection between first output node No1 and data output node DON may be opened.

The second output switch transistor OSWTr2 may be connected between the second output node No2 and the data output node DON. When the second output switch transistor OSWTr2 is turned on by the switch control signal CTL_S, it may be short-circuited between the second output node No2 and the data output node DON. When the second output switch transistor OSWTr2 is turned off by the switch control signal CTL_S, the connection between second output node No2 and the data output node DON may be opened.

The first and second output switch transistors OSWTr1 and OSWTR2, based on the switch control signal CTL_S, may provide the m-th data output signal OUT_S[m] output from the first_first output node No1 and the first_second output node No2 to the data output node DON or block the output m-th data output signal OUT_S[m]. According to an embodiment, the first and second output switch transistors OSWTr1 and OSWTr2 may be NMOS transistors, but are not limited thereto.

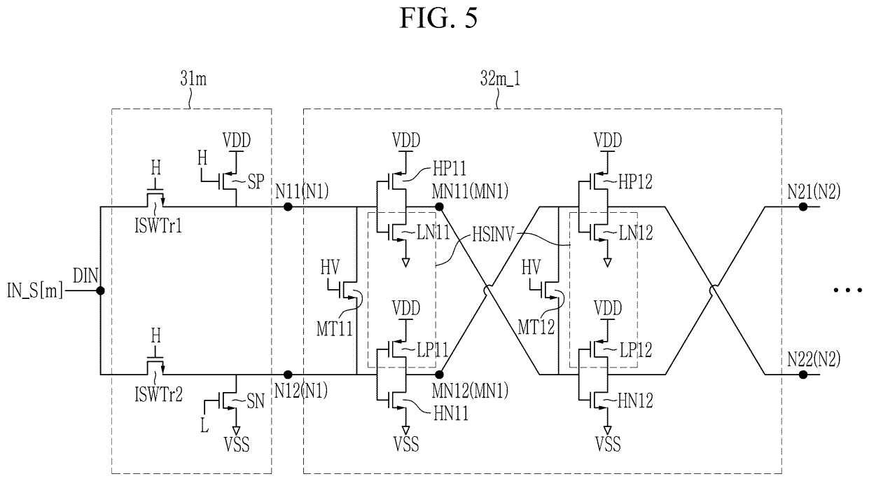

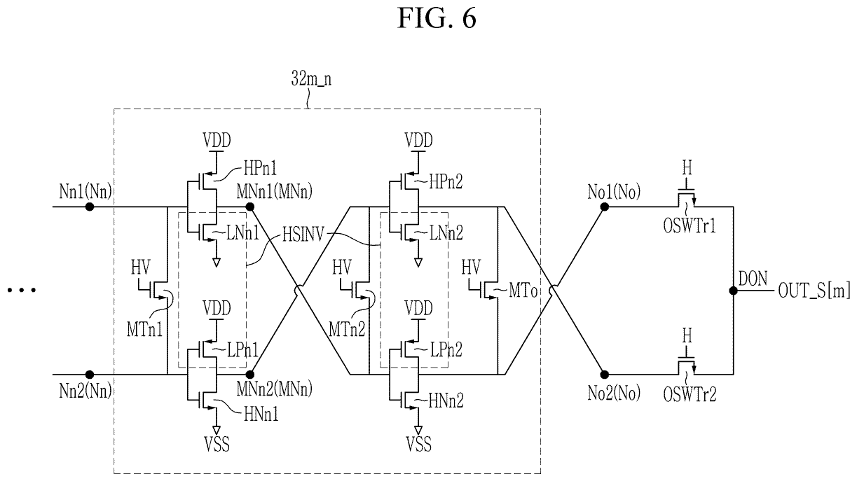

Referring now to FIG. 5 an FIG. 6, which are views to explain the operation of the m-th data signal transmitter of FIG. 2 when the data signal transmitter is the active operation mode, during the active operation mode, the m-th data input signal IN_S[m] may be input through the data input node DIN. During the active operation mode, the high level signal of the turn on level may be input to the switch control signal CTL_S, the high level signal of the turn off level may be input to the first standby control signal CTL1, the low level signal of the turn off level may be input to the second standby control signal CTL2, and the high level signal HV of the turn on level may be input to the active mode enable signal AM_EN.

According to an embodiment, to turn on the first_first to first_second mode setting transistors MT11 to MT12 and the n-th_1 to n-th_2 mode setting transistors MTn1 to MTn2, the voltage magnitude of the high level signal HV of the turn on level input to the active mode enable signal AM_EN may be greater than the power source voltage VDD. In response to the input of the standby control signal CTLs and the active mode enable signal AM_EN, the first and second input switch transistors ISWTr1 and ISWTR2, the first and second output switch transistors OSWTr1 and OSWTR2, the first_first to first_second mode setting transistors MT11 to MT12, the n-th_1 to n-th_2 mode setting transistors MTn1 to MTn2, and the output mode setting transistor MTo may be turned on.

As the first_first to first_second mode setting transistors MT11 to MT12, the n-th_1 to n-th_2 mode setting transistors MTn1 to MTn2, and the output mode setting transistor MTo are turned on, a conduction channel may be formed between the first_first node N11 and the first_second node N12, between the first_first middle node MN11 and the first_second middle node MN12, between the n-th_1 node Nn1 and the n-th_2 node Nn2, between the n-th_1 middle node MNn1 and the n-th_2 middle node MNn2, and between the first output node No1 and the second output node No2.

In response to the formation of the conduction channel, the first_first node N11 and the first_second node N12 may form one first node N1, the first_first middle node MN11 and the first_second middle node MN12 may form one first middle node MN1, the second_first node N21 and the second_second node N22 may form one second node N2, the n-th_1 node Nn1 and the n-th_2 node Nn2 may form one n-th node Nn, the n-th 1 middle node MNn1 and the n-th_2 middle node MNn2 may form one n-th middle node MNn, and the first output node No1 and the second output node No2 may one output node No. And, in response to the formation of the conduction channel, the first_first CMOS inverter CM_INV11 and the first_third CMOS inverter CM_INV13 may be in parallel connected between the first node N1 and the first middle node MN1, the first_second CMOS inverter CM_INV12 and the first_fourth CMOS inverter CM_INV14 may be in parallel connected between the first middle node MN1 and the second node N2, the n-th_1 CMOS inverter CM_INVn1 and the n-th_3 CMOS inverter CM_INV13 may be in parallel connected between the n-th node Nn and the n-th middle node MNn, and the n-th_2 CMOS inverter CM_INVn2 and the n-th_4 CMOS inverter CM_INVn4 may be in parallel connected between the n-th middle node MNn and the output node No.

A CMOS inverter composed of a transistor with a small threshold voltage may have a shorter propagation delay time characteristic than a CMOS inverter composed of a transistor with a large magnitude of the threshold voltage. Accordingly, due to the formation of the conduction channel, between the first node N1 and the first middle node MN1, the first_first low-threshold voltage NMOS transistor LN11 and the first_first low-threshold voltage PMOS transistor LP11 may operate together as a single high-speed CMOS inverter (HSINV) that operates based on low-threshold voltage.

Similarly, between the second middle node MN2 and the second node N2, the first_second low-threshold voltage NMOS transistor LN12 and the first_second low-threshold voltage PMOS transistor LP12 operate together as one high-speed CMOS inverter (HSINV) that operates based on low-threshold voltage. Between the n-th node (Nn) and the n-th middle node MNn, the n-th_1 low-threshold voltage NMOS transistor LNn1 and the n-th_1 low-threshold voltage PMOS transistor LPn1 may operate together as a single high-speed CMOS inverter (HSINV) operated as devices that operate based on the low-threshold voltage. Between the n-th middle node MNn and the output node No, the n-th_2 low-threshold voltage NMOS transistor LNn2 and the n-th_2 low-threshold voltage PMOS transistor LPn2 may operate together as a single high-speed CMOS inverter (HSINV) that operates based on low-threshold voltage.

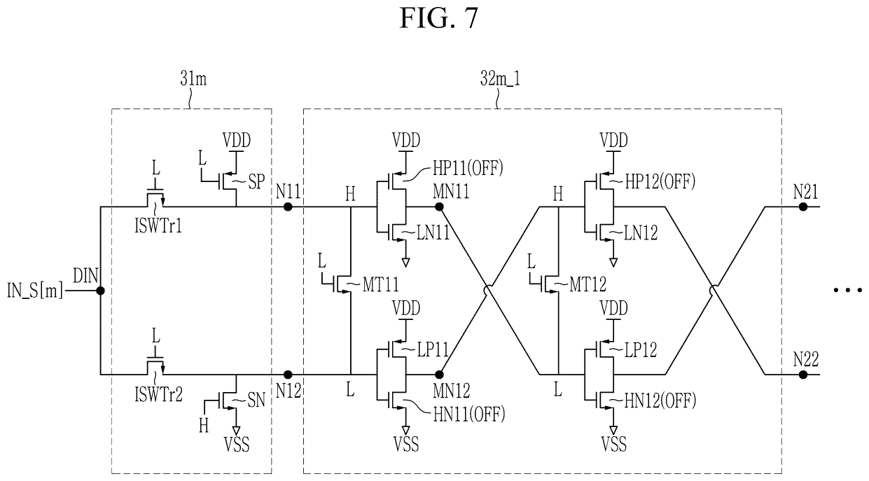

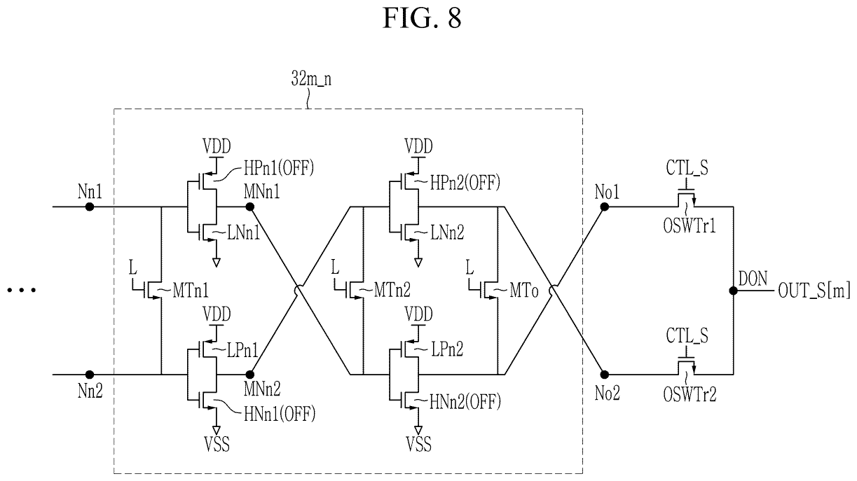

FIG. 7 and FIG. 8 are views to explain an operation of a data signal transmitter according to an embodiment. FIG. 7 and FIG. 8 are the views to explain the operation of the m-th data signal transmitter 30m of FIG. 2 when the data signal transmitter is the standby operation mode. Referring to FIG. 2 to FIG. 4, and FIG. 7 and FIG. 8, during the standby operation mode, the m-th data input signal IN_S[m] may be not input to the m-th data signal transmitter 30m. According to an embodiment, during the standby operation mode, the m-th data input signal IN_S[m] may be input to the m-th data signal transmitter 30m, but the input of the m-th data input signal IN_S[m] for the m-th data signal transmitter 30m may be blocked by the turn off operation of the first and second input switch transistors ISWTr1 and ISWTR2, which will be described later. Moreover, during the standby operation mode, the low level signal of the turn off level may be input to the switch control signal CTL_S, the low level signal of the turn on level may be input to the first standby control signal CTL1, the high level signal of the turn on level may be input to the second standby control signal CTL2, and the low level signal of the turn off level may be input to the active mode enable signal AM_EN.

Through the input of the standby control signal CTLs and the active mode enable signal AM_EN, the first and second input switch transistors ISWTr1 and ISWTR2, the first and second output switch transistors OSWTr1 and OSWTR2, the first_first to first_second mode setting transistors MT11 to MT12, the n-th_1 to n-th_2 mode setting transistors MTn1 to MTn2, and the output mode setting transistor MTo may be turned off, and the standby voltage PMOS transistor SP and the standby voltage NMOS transistor NP may be turned on.

The first_first CMOS inverter CM_INV11, the first_fourth CMOS inverter CM_INV14, . . . , the n-th_1 CMOS inverter CM_INVn1, and the n-th_4 CMOS inverter CM_INV14 may be connected in series in a form of an inverter chain between the first_first node N11 and the first output node No1. The first_third CMOS inverter CM_INV13, the first_second CMOS inverter CM_INV12, . . . , the n-th_3 CMOS inverter CM_INVn3, and the n-th_2 CMOS inverter CM_INV12 may be connected in series in a form of an inverter chain between the first_second node N12 and the second output node No2.

Through the turning off of the first and second input switch transistors ISWTr1 and ISWTR2, the first and second output switch transistors OSWTr1 and OSWTR2, the first_first to first_second mode setting transistors MT11 to MT12, the n-th_1 to n-th_2 mode setting transistors MTn1 to MTn2, and the output mode setting transistor MTo, the first_first CMOS inverter CM_INV11, the first_fourth CMOS inverter CM_INV14, . . . , the n-th_1 CMOS inverter CM_INVn1, and the n-th_4 CMOS inverter CM_INV14, and the first_third CMOS inverter CM_INV13, the first_second CMOS inverter CM_INV12, . . . , the n-th_3 CMOS inverter CM_INVn3, and the n-th_2 CMOS inverter CM_INV12 may be electrically separated.

During the standby operation mode, through the standby voltage PMOS transistor SP, the power source voltage VDD may be applied to the first_first node N11 as the standby voltage, and the high level signal may be input to the first_first node N11. The first_fourth CMOS inverter CM_INV14, . . . , the n-th_1 CMOS inverter CM_INVn1, and the n-th_4 CMOS inverter CM_INVn4, which are placed at the next state of the first_first CMOS inverter CM_INV11 may sequentially invert the single corresponding to the standby voltage. For example, during the standby operation mode, the high level signal of the first_first node N11 may be inverted by the first_first CMOS inverter CM_INV11 to be output at the first_first middle node MN11 as a low level signal. Likewise, the low level signal of the first_first middle node MN11 may be inverted by the first_fourth CMOS inverter CM_INV14 to be output as a high level signal at the second_first node N21. The high level signal of the n-th_1 node Nn1 may be inverted by the n-th_1 CMOS inverter CM_INVn1 to be output as a low level signal at the n-th_1 middle node MNn1, and the low level signal of the n-th_1 middle node MNn1 may be inverted by the n-th_4 CMOS inverter to be output as a high level signal at the first output node No1.

During the standby operation mode, the outputs of the first_first CMOS inverter CM_INV11, the first_fourth CMOS inverter CM_INV14, . . . , the n-th_1 CMOS inverter CM_INVn1, and the n-th_4 CMOS inverter CM_INV14 may be maintained in a static state. Also, during the standby operation mode, the ground voltage VSS may be applied to the first_second node N12 as a standby voltage through the standby voltage NMOS transistor SN, and the low level signal may be input to the first_second node N12. The first_second CMOS inverter CM_INV12, . . . , the n-th_3 CMOS inverter CM_INVn3, and the n-th_2 CMOS inverter CM_INVn2, which are placed at the nest stage of the first_third CMOS inverter CM_INV12, may sequentially invert the signal corresponding to the standby voltage. For example, during the standby operation mode, a low level signal of the first_second node N12 may be inverted by the first_third CMOS inverter CM_INV13 to be output at the first_second middle node MN12 as a high level signal. Likewise, the high level signal of the first_second middle node MN12 may be inverted by the first_second CMOS inverter CM_INV12 to be output as a low level signal at the second_second node N22. The low level signal of the n-th_2 node Nn2 may be inverted by the n-th_3 CMOS inverter CM_INVn3 to be output as a high level signal at the n-th_2 middle node MNn2, and the high level signal of the n-th_2 middle node MNn2 may be inverted by the n-th_2 CMOS inverter CM_INVn2 to be output as a low level signal at the second output node No2.

During the standby operation mode, the outputs of the first_third CMOS inverter CM_INV13, the first_second CMOS inverter CM_INV12, . . . , the n-th_3 CMOS inverter CM_INVn3, and the n-th_2 CMOS inverter CM_INV12 may be maintained in a static state. In addition, by providing the standby voltage through the standby voltage PMOS transistor SP and the standby voltage NMOS transistor SN, during the standby operation mode, the first_first high-threshold voltage PMOS transistor HP11, the first_first high-threshold voltage NMOS transistor HN11, the first_second high-threshold voltage PMOS transistor HP12, the first_second high-threshold voltage NMOS transistor HN12, the n-th_1 high-threshold voltage PMOS transistor HPn1, the n-th_1 high-threshold voltage NMOS transistor HNn1, the n-th_2 high-threshold voltage PMOS transistor HPn2, and the n-th_2 high-threshold voltage NMOS transistor HNn2 may be turned off. Advantageously, a transistor with a larger threshold voltage magnitude typically has a characteristic in which less leakage current flows when being turned off, relative to a transistor with a small threshold voltage magnitude.

During the standby operation mode, as the output of the (m_1)-th to (m_n)-th repeater blocks 32m_1 to 32m_n can be maintained in a static state, during the static state, the high-threshold voltage transistors HP11 to HPn2 and HN11 and HNn2 may be turned off to block a leakage current from occurring in the CMOS inverter within the (m_1)-th to (m_n)-th repeater blocks 32m_1 to 32m_n.

Additionally, referring to FIG. 5 and FIG. 6, the data signal transmitter 30 of the present disclosure, without adding a separate power gating circuit, may improve the data transfer speed in the active operation mode and reduce the leakage current in the standby operation mode through the arrangement of the CMOS inverter including the mode setting transistor and the transistors with the different magnitudes of the threshold voltages. The data signal transmitter 30 in the present disclosure may increase the area efficiency of the data signal transmitter 30 by not disposing the power gating circuit.

In the data signal transmitter 30 of the present disclosure, as there is no separate configuration between the power source voltage VDD and the CMOS inverter and the ground voltage VSS of the CMOS inverter, a performance degradation of the CMOS inverter due to a voltage drop (IR Drop) may be improved.

In the data signal transmitter 30 of the present disclosure, because there is no power gating circuit between the power source voltage VDD and the CMOS inverter and the ground voltage VSS of the CMOS inverter, the data signal transmitter 30 does not require a generation circuit of a virtual power source voltage and a virtual ground voltage for the power gating circuit.

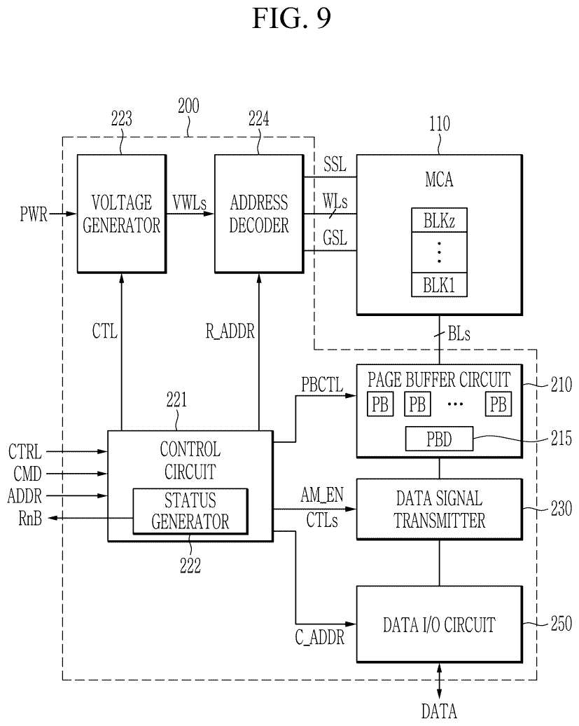

Referring to FIG. 9, a semiconductor device 100 according to an embodiment may include a non-volatile memory that stores a data in a semi-permanent or substantially permanent form. The semiconductor device 100 may include a memory cell array 110 and a peripheral circuit 200. The peripheral circuit 200 may include a page buffer circuit 210, a control circuit 221, a voltage generator 223, an address decoder 224, a data signal transmitter 230, and a data input/output circuit 250. Although not shown in FIG. 1, the peripheral circuit 200 may further include an input/output interface, a column logic, a pre-decoder, a temperature sensor, the like.

The memory cell array 110 may be connected to the address decoder 224 through a string selection line SSL, a plurality of word lines WLs, and a ground selection line GSL. Also, the memory cell array 110 may be connected to the page buffer circuit 210 through a plurality of bit lines BLs. The memory cell array 110 may include a plurality of non-volatile memory cells connected to the plurality of word lines WLs and the plurality of bit lines BLs. According to an embodiment, the memory cell array 110 may be a three-dimensional memory cell array formed in a three-dimensional structure (or a vertical structure) on the substrate. In this case, the memory cell array 110 may include vertical memory cell strings including a plurality of memory cells that are formed by stacking each other.

The control circuit 221 may receive a control signal CTRL, a command signal CMD, and an address signal ADDR from a memory controller (not shown), and control an erase loop, a program loop, and a read operation of the semiconductor device 100 based on the control signal CTRL, the command signal CMD, and the address signal ADDR. For example, the control circuit 221 may generate a control signal including a control signal CTL for controlling the voltage generator 223, a page buffer control signal PBCTL for controlling the page buffer circuit 210, and a standby control signal CTLs and an active mode enable signal AM_EN for controlling the data signal transmitter 230 based on the command signal CMD. The control circuit 221 may generate a row address R_ADDR and a column address C_ADDR based on the address signal ADDR. The control circuit 221 may provide the row address R_ADDR to the address decoder 224 and the column address C_ADDR to the data input/output circuit 250. The control circuit 221 may include a state signal generator 222 that generates a state (or a ready/busy) signal RnB indicating the operation state of the semiconductor device 100.

The address decoder 224 may be connected to the memory cell array 110 through the string selection line SSL, the plurality of word lines WLs, and the ground selection line GSL. During the program operation or the read operation, the address decoder 224 may determine one among the plurality of word lines WLs as a selection word line, and the remaining word lines except for the selection word line among the plurality of word lines WLs as non-selection word lines based on the row address R_ADDR provided from the control circuit 450.

The voltage generator 223 may generate word line voltages VWLs required for the operation of the semiconductor device 100 by using a power PWR based on the internal control signal CTL provided from the control circuit 221. The word line voltages VWLs generated from the voltage generator 223 may be applied to the plurality of word lines WLs through the address decoder 224.

The page buffer circuit 210 may be connected to the memory cell array 110 through the plurality of bit lines BLs. The page buffer circuit 210 may include a plurality of page buffer (PB) and a page buffer driver (PBD) 215. The page buffer circuit 210 may temporarily store a data to be programmed in a selected page during the program operation, and may temporarily store a data read from the selected page during the read operation. The page buffer driver 215 may transmit a program data provided from the data signal transmitter 230 to the plurality of page buffers PB during the program operation, and may provide the data provided from the plurality of page buffers PB to the data signal transmitter 230 during the read operation. The page buffer driver 215 in the page buffer circuit 210 during the read operation may correspond to the driver circuit 10 of FIG. 1.

The data signal transmitter 230 may correspond to the data signal transmitter 30 of FIG. 1 to FIG. 8. The data signal transmitter 230 includes the mode setting transistor controlled by the active mode enable signal AM_EN and the standby voltage generator controlled by the standby control signal CTLs, thereby preventing the leakage current from occurring while improving the propagation delay time without the need for a separate power gating circuit. The description of the data signal transmitter 230 may be replaced with the explanation of the data signal transmitter 30 of FIG. 1 to FIG. 8.

The data input/output circuit 250 may be connected to the page buffer circuit 210 through the data signal transmitter 230. During the program operation, the data input/output circuit 250 may receive a program data from the memory controller (not shown), and provide the program data DATA to the page buffer circuit 210 through the data signal transmitter 230 based on the column address C_ADDR provided from the control circuit 221. During the read operation, the data input/output circuit 250 may receive the read data DATA stored in the page buffer circuit 210 through the data signal transmitter 230 based on the column address C_ADDR provided from the control circuit 221, and transmit the read data DATA to the memory controller (not shown). During the read operation, the data input/output circuit 250 may corresponding to the receiver circuit 50 of FIG. 1.

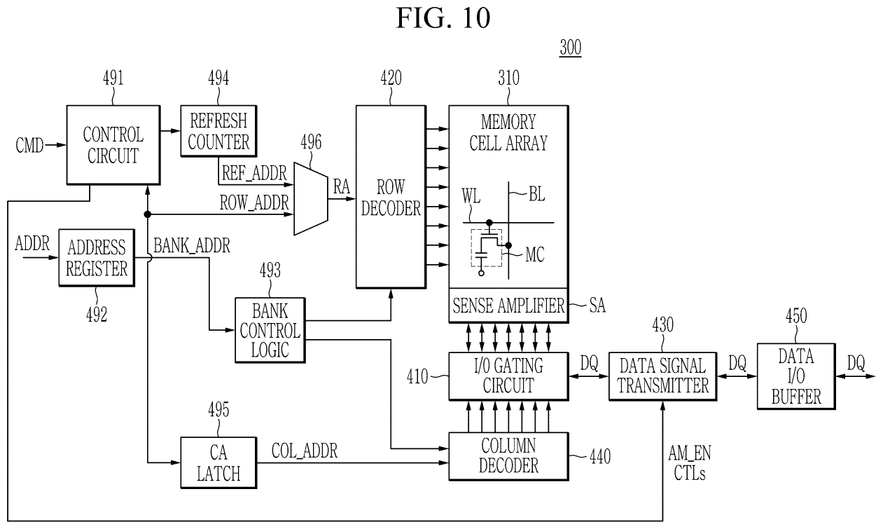

Referring to FIG. 10, the semiconductor device 300 according to an embodiment, may include a volatile memory where temporarily store a data or various software codes are executed. The semiconductor device 300 may include a memory cell array 310, a sense amplifier SA, a row decoder 420, a column decoder 440, a control circuit 491, an address resistor 492, a bank control logic 493, a refresh counter 494, a column address latch 495, a row address multiplexer 496, an input/output gating circuit 410, a data signal transmitter 430, and a data input/output buffer 450.

The memory cell array 310 may include a predetermined number of memory banks (not shown) included in memory channels (not shown). Also, according to an embodiment, each of the sense amplifier SA, the row decoder 420, and the column decoder 440 may include a plurality of bank sense amplifiers, a plurality of bank row decoders, and a plurality of bank column decoders, which are connected to each memory bank, but it is not limited thereto.

The memory cell array 310 may include a plurality of word lines WL, a plurality of bit lines BL, and a plurality of memory cells MC positioned at the intersections of the word lines WL and the bit lines BL. The semiconductor device 100 may perform a read operation or a write operation of a data DQ for the plurality of memory cells MC. The memory cell MC may include a 1T1C structure including one transistor and one capacitor. The sense amplifier SA may include a plurality of bit line sense amplifiers connected to the plurality of bit lines BL of the memory cell array 310. The plurality of bit line sense amplifiers may detect a data input/output through the bit line BL and input/output the detected data.

The control circuit 491 may control the operation of the semiconductor device 300. For example, the control logic circuit 491 may generate control signals so that the semiconductor device 300 performs the write operation or the read operation. For example, the control circuit 491 may generate a control signal including the standby control signal CTLs and the active mode enable signal AM_EN for controlling the data signal transmitter 430. Although not shown, the control logic circuit 491 may include a command decoder for decoding the received command CMD and a mode resistor for setting the operation mode of the semiconductor device 300.

The address resistor 492 may receive an address ADDR including a bank address BANK_ADDR, a row address ROW_ADDR, and a column address COL_ADDR from the memory controller (not shown). The address resistor 492 may provide the received bank address BANK_ADDR to the bank control logic 493 and the received row address ROW_ADDR to the row address multiplexer 496. The bank control logic 493 may generate bank control signals in response to the bank address BANK_ADDR. In response to the bank control signals, the row decoder 420 and the column decoder 440 may activate the corresponding bank.

The row address multiplexer 496 may receive the row address ROW_ADDR from the address resistor 492 and the refresh row address REF_ADDR from the control circuit 491. The row address multiplexer 496 may selectively output the row address ROW_ADDR or the refresh row address REF_ADDR as a row address RA. The row address RA) output from the row address multiplexer 496 may be applied to the row decoder 420.

The row decoder 420 may decode the row address RA output from the row address multiplexer 496 and activate the word line corresponding to the row address RA. The column address latch 495 may receive the column address COL_ADDR from the address resistor 492 and temporarily store the received column address COL_ADDR. Additionally, the column address latch 495 may gradually increase the received column address COL_ADDR in a burst mode. The column address latch 495 may apply the temporarily stored or gradually increased column address to the column decoder 440.

The column decoder 440 may activate the bit line sense amplifier of the sense amplifier SA corresponding to the bank address BANK_ADDR and the column address COL_ADDR through the input/output gating circuit 410, in relation to the bank activated by the bank control logic 493. The input/output gating circuit 410 may include a circuit that gates an input/output data, an input data mask logic, data latches that store a data output from the memory cell array 310, a driver that outputs a data stored in the data latch, and write drivers that write a data to the memory cell array 310. During the read operation, the input/output gating circuit 410 may correspond to the driver circuit 10 of FIG. 1.

The data signal transmitter 430 may correspond to the data signal transmitter 30 of FIG. 1 to FIG. 8. The data signal transmitter 430 includes the mode setting transistor controlled by the active mode enable signal AM_EN and the standby voltage generator controlled by the standby control signal CTLs, thereby preventing the leakage current from occurring while improving the propagation delay time without the need for a separate power gating circuit. The description of the data signal transmitter 430 may be replaced with the explanation of the data signal transmitter 30 in FIG. 1 to FIG. 8.

The data input/output buffer 450 may provide the data DQ to the input/output gating circuit 410 based on the clock signal during the write operation. The data input/output buffer 450 may provide the data DQ to the memory controller (not shown) based on the clock signal during the read operation. During the read operation, the data input/output buffer 450 may correspond to the receiver circuit 50 of FIG. 1.

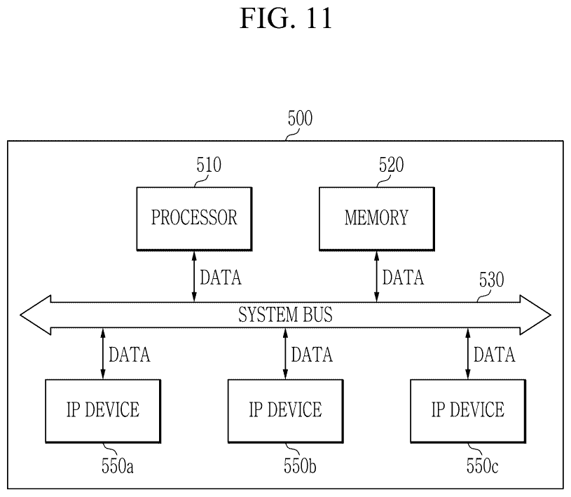

Referring to FIG. 11, the semiconductor device 500 according to embodiment may process and manage instructions, perform data processing operations, and perform various functions by encompassing a plurality of function blocks with various functions. The semiconductor device 500 may include a processor 510, a memory 520, a bus 530, and a plurality of IP devices 550a to 550c.

The processor 510 may include at least one among a processor such as a microprocessor, a digital signal processor, a central processing unit (CPU), a graphics processing unit (GPU), a neural processing unit (NPU), a data processing unit (DPU), or logic devices that performs the similar functions thereto. The memory 520 may be a storage device that stores a data and/or instructions, etc. Although not clearly shown, the memory 520 as an operation memory for the operation of the processor 510 and may include high-speed DRAM and/or SRAM according to an embodiment.

The plurality of IP devices 550a to 550c may be a circuit block that performs a specific function within the semiconductor device 500. According to an embodiment, the plurality of IP devices 550a to 550c may include a special function register. The processor 510 may process a data by using the special function resistor. Although the plurality of IP devices 550a to 550c are shown as three devices, the number of the devices does not limit the technical scope of the present disclosure.

The processor 510, the processor 520, and the plurality of IP devices 550a to 550c may be combined with each other through a bus 530. According to an embodiment, the bus 530 may be an advanced microcontroller bus architecture (AMBA), and the AMBA may be a standard bus specification for connection and management of the plurality of IP devices 550a to 550c within the semiconductor device 500. The processor 510, the processor 520, and the plurality of IP devices 550a to 550c may transmit and receive a data with different configurations through the bus 530.

In the operation of the semiconductor device 500, one of the processor 510, the processor 520, and the plurality of IP devices 550a to 550c may operate as a master device, and the other may operate as a slave device that responds to the master device. The master device is a device that plays a leading role in using the bus 530, and the master device may use the bus 530 as the main device. For example, when the master device instructs a data writing operation for the slave device, the master device may provide the data along with the control signal to the slave device through the bus 530. In the process of providing the data, the interface circuit of the master device may correspond to the driver circuit 10 of FIG. 1, and the bus 530 may correspond to the data signal transmitter 30 of FIG. 1 to FIG. 8, and the interface circuit of the slave device may correspond to the receiver circuit 50 of FIG. 1.

In relation to the data signal transmission, the bus 530 may include a mode setting transistor, a standby voltage generator, and a CMOS inverter with different magnitudes of the threshold voltages. The bus 530, through configurations such as the mode setting transistor, the standby voltage generator, and the CMOS inverter, may prevent the leakage current from occurring while improving the propagation delay time without arranging a separate power gating circuit between the power and the ground. The description of the components may be replaced with the explanation of the data signal transmitter 30 in FIG. 1 to FIG. 8.

While these inventive concepts have been described in connection with what is presently considered to be practical embodiments, it is to be understood that the inventive concepts are not limited to such example embodiments. On the contrary, the inventive concepts are intended to cover various modifications and equivalent arrangements included within the spirit and scope of the appended claims.

What is claimed is:

1. A data signal transmitter, comprising:
a standby voltage generator configured to selectively output: (i) a data signal during an active operation mode, and (ii) first and second standby voltages, having different magnitudes from each other, during a standby operation mode; and
a repeater block including:
a first CMOS inverter configured to receive the first standby voltage during the standby operation mode, said first CMOS inverter including a first PMOS transistor and a first NMOS transistor having different threshold voltage magnitudes; and
a second CMOS inverter configured to receive the second standby voltage during the standby operation mode, said second CMOS inverter including a second PMOS transistor having a threshold voltage magnitude that is smaller than the magnitude of the threshold voltage of the first PMOS transistor, and a second NMOS transistor having a threshold voltage magnitude that is greater than the magnitude of the threshold voltage of the first NMOS transistor.

2. The transmitter of claim 1,
wherein the standby voltage generator is further configured to provide the data signal though first and second nodes, being different from each other, to the repeater block during the active operation mode; and
wherein the repeater block further includes:
a first mode setting transistor having a first terminal electrically connected to the first node and an input terminal of the first CMOS inverter, and a second terminal electrically connected to the second node and an input terminal of the second CMOS inverter; and
a second mode setting transistor having a first terminal electrically connected to a second middle node and an output terminal of the second CMOS transistor, and a second terminal electrically connected to a first middle node and an output terminal of the first CMOS transistor.

3. The transmitter of claim 2, wherein the first and second mode setting transistors are turned on and the first and second CMOS inverters are connected in parallel between the first node and the first middle node, during the active operation mode.

4. The transmitter of claim 3, wherein the standby voltage generator is configured to block the first and second standby voltages and provide the data signal from the data input node to the repeater block through the first and second nodes, during the active operation mode.

5. The transmitter of claim 4, wherein the standby voltage generator is configured to provide an open circuit between the data input node and the first node, and between the data input node and the second node, during the standby mode of operation mode.

6. The transmitter of claim 2,
wherein the repeater block further includes:
a third CMOS inverter having an input terminal electrically coupled to the output terminal of the first CMOS inverter and the first middle node; and
a fourth CMOS inverter having an input terminal electrically coupled to the output terminal of the second CMOS inverter and the second middle node.

7. The transmitter of claim 1, wherein the standby voltage generator is configured to provide: the first standby voltage at a magnitude equivalent to a power supply voltage for the first CMOS inverter, and the second standby voltage at a magnitude equivalent to a ground voltage for the second CMOS inverter, during the standby operation mode.

8. The transmitter of claim 7, wherein the first CMOS inverter is configured to output a low level signal, and the second CMOS inverter is configured to output a high level signal, during the standby operation mode.

9. The transmitter of claim 1, further comprising:
a plurality of repeater blocks including the repeater block;
a first switch transistor having a first terminal electrically coupled to a first output node associated with a final repeater block within the plurality of repeater blocks; and
a second switch transistor having a first terminal electrically coupled to a second output node associated with the final repeater block.

10. The transmitter of claim 9, wherein a second terminal of the first switch transistor is electrically connected to a second terminal of the second switch transistor; and wherein the first and second switch transistors are configured to electrically connect the first output node associated with a final repeater block to the second output node associated with the final repeater block during the active operation mode.

11. A data signal transmitter, comprising:
a first mode setting transistor connected between a first node to which a power source voltage is provided in a standby operation mode and a second node that is different from the first node and to which a ground voltage is provided in the standby operation mode;
a first high-threshold voltage transistor including a gate terminal connected to the first node and a source terminal to which a power source voltage is applied;
a first low-threshold voltage transistor including a gate terminal connected to the first node and a source terminal that is grounded and forming a threshold voltage smaller than the magnitude of the threshold voltage of the first high-threshold voltage transistor;
a second low-threshold voltage transistor including a gate terminal connected to the second node and a source terminal to which a power source voltage is applied; and
a second high-threshold voltage transistor including a gate terminal connected to the second node and a source terminal that is grounded, and forming a threshold voltage greater than the magnitude of the threshold voltage of the second low-threshold voltage transistor.

12. The transmitter of claim 11, wherein the first high-threshold voltage transistor and the second low-threshold voltage transistor are PMOS transistors; and wherein the first low-threshold voltage transistor and the second high-threshold voltage transistor are NMOS transistors.

13. The transmitter of claim 11, wherein in an active operation mode different from the standby operation mode, a high level signal is input to the gate terminal of the first mode setting transistor, and a conduction channel is formed between the first node and the second node.

14. The transmitter of claim 13, wherein the voltage magnitude of the high level signal is greater than the magnitude of the power source voltage.

15. The transmitter of claim 13, further comprising:
a second mode setting transistor electrically connected between the drain terminal of the first low-threshold voltage transistor and the drain terminal of the second low-threshold voltage transistor; and
wherein, in the active operation mode, if the first and second mode setting transistor is turned on, the first low-threshold voltage transistor and the second low-threshold voltage transistor are operated together as an inverter.

16. The transmitter of claim 15, further comprising:
a third low-threshold voltage transistor including a gate terminal connected to the drain terminal of the first low-threshold voltage transistor and a source terminal to which a power source voltage is applied, and having a threshold voltage smaller than the magnitude of the threshold voltage of the first high-threshold voltage transistor; and
a third high-threshold voltage transistor including a gate terminal connected to the drain terminal of the first low-threshold voltage transistor and a source terminal that is grounded, and having a threshold voltage greater than the magnitude of the threshold voltage of the second low-threshold voltage transistor.

17. The transmitter of claim 11, further comprising:
a first switch transistor connected between the first node and a data input node;
a second switch transistor connected between the data input node and the second node;
a first standby voltage transistor including a drain terminal connected to the first node and a source terminal to which a power source voltage is applied; and
a second standby voltage transistor that includes a drain terminal connected to the second node and a source terminal that is grounded.

18. The transmitter of claim 17, wherein in the standby operation mode, the first and second switch transistors are turned off and the first mode setting transistor is turned off.

19. The transmitter of claim 18,
wherein the first high-threshold voltage transistor and the second high-threshold voltage transistor are turned off and block a leakage current; wherein the first low-threshold voltage transistor outputs a low level signal; and wherein the second low-threshold voltage transistor outputs a high level signal.

20. A integrated circuit device, comprising:
a driver circuit configured to transmit data signals through a transmission line;
a receiver circuit configured to receive the data signals through the transmission line; and
a data signal transmitter extending between portions of the transmission line, said data signal transmitter including:
a standby voltage generator configured to provide first and second standby voltages, having different magnitude from each other, depending on whether the data signal of the driver circuit is output or not;
a first CMOS inverter that is provided with the first standby voltage and includes a first PMOS transistor and a first NMOS transistor with different threshold voltage magnitudes; and
a second CMOS inverter that is provided with the second standby voltage and includes a second PMOS transistor with a threshold voltage less than the magnitude of the threshold voltage of the first PMOS transistor and a second NMOS transistor with a threshold voltage greater than the magnitude of the threshold voltage of the first NMOS transistor.
